(19) United States
(12) Patent Application Publication
(10) Pub. No.: US 2024/0146832 A1
(43) Pub. Date: May 2, 2024

(54) COVER WINDOW AND DISPLAY DEVICE INCLUDING COVER WINDOW

(71) Applicant: Samsung Display Co., LTD., Yongin-si (KR)

(72) Inventors: HYUNHO JEONG, Yongin-si (KR); Dong Ho KIM, Yongin-si (KR); Ju Suk OH, Yongin-si (KR)

(73) Assignee: Samsung Display Co., LTD., Yongin-si (KR)

(21) Appl. No.: 18/495,120

(22) Filed: Oct. 26, 2023

(30) Foreign Application Priority Data
Oct. 27, 2022 (KR) 10-2022-0140497

(51) Int. Cl. H04M 1/02; G02F 1/1333

(52) U.S. Cl. CPC H04M 1/0266; G02F 1/133308; G06F 3/14

(57) ABSTRACT

A display device includes a display panel including a display area including a plurality of pixels and a peripheral area disposed adjacent to the display area, and a cover window including a transmissive area corresponding to the display area and a non-transmissive area corresponding to the peripheral area. The cover window includes a base member, a first print layer formed on a first surface of the base member, and a second print layer formed on the first print layer. The second print layer includes an opening exposing the first print layer, the opening is disposed in the non-transmissive area, the first print layer and the second print layer have a same color, and a gloss of the first print layer is greater than a gloss of the second print layer.

### CROSS-REFERENCE TO RELATED APPLICATION(S)

This application claims priority to and the benefits of Korean Patent Application No. 10-2022-0140497 under 35 U.S.C. § 119, filed in the Korean Intellectual Property Office (KIPO), on Oct. 27, 2022, the entire contents of which are incorporated herein by reference.

### BACKGROUND

### (a) Technical Field

The disclosure relates to a cover window and a display device including the cover window.

### (b) Description of the Related Art

A display device such as a liquid crystal display (LCD), an organic light emitting diode (OLED) display, and the like includes a display panel that includes multiple pixels for displaying an image and a cover window for protecting the display panel.

The cover window may include a transmissive area through which light is transmitted and a non-transmissive area through which light is not transmitted. A print layer is disposed for blocking light in the non-transmissive area.

The above information disclosed in this Background section is only for enhancement of understanding of the background of the disclosure, and therefore it may contain information that does not form the prior art that is already known in this country to a person of ordinary skill in the art.

### SUMMARY

Marks such as letters, numbers, and patterns that identify a display device or indicate information about a corresponding display device may be disposed on a print layer.

Embodiments of the disclosure are intended to improve visibility of a mark represented by a print layer while reducing manufacturing cost of a print layer included in a cover window of a display device.

According to an embodiment, a display device may include a display panel including a display area including a plurality of pixels and a peripheral area disposed adjacent to the display area, and a cover window including a transmissive area corresponding to the display area and a non-transmissive area corresponding to the peripheral area. The cover window may include a base member, a first print layer formed on a first surface of the base member, and a second print layer formed on the first print layer. The second print layer may include an opening exposing the first print layer, the opening may be disposed in the non-transmissive area, the first print layer and the second print layer may have a same color, and a gloss of the first print layer may be greater than a gloss of the second print layer.

The gloss of the first print layer may be greater than or equal to about 70 gloss unit (GU), and the gloss of the second print layer may be less than or equal to about 10 GU.

A difference between the gloss of the first print layer and the gloss of the second print layer may be greater than or equal to about 60 GU.

The second print layer may include a material containing a matting agent.

The matting agent is greater than or equal to about 10% of the material of the second print layer.

The first print layer may include a material containing the matting agent, and the matting agent may be in a range of about 0% to about 3% of the material of the first print layer.

The first print layer and the second print layer may be only print layers disposed on the first surface of the base member.

The first print layer may contact the base member and the second print layer.

The first surface may be a plane that faces the display panel.

In a plan view on the first surface, the opening may have a shape that indicates information of the display device.

According to an embodiment, a cover window may include a base member, a first print layer formed on a first surface of the base member, and a second print layer formed on the first print layer. The second print layer may include an opening exposing the first print layer, the first print layer and the second print layer may have a same color, and a gloss of the first print layer may be greater than a gloss of the second print layer.

The gloss of the first print layer may be greater than or equal to about 70 gloss unit (GU), and the gloss of the second print layer may be less than or equal to about 10 GU.

A difference between the gloss of the first print layer and the gloss of the second print layer may be greater than or equal to about 60 GU.

The second print layer may include a material containing a matting agent.

The matting agent may be greater than or equal to about 10% of the material of the second print layer.

The first print layer may include a material containing the matting agent, and the matting agent may be in a range of about 0% to about 3% of the material of the first print layer.

The first print layer and the second print layer may be only print layers disposed on the first surface of the base member.

The first print layer may contact the base member and the second print layer.

In a plan view on the first surface, the opening may have a shape that indicates information of the display device.

According to an embodiment, a display device may include a display panel including a display area including a plurality of pixels and a peripheral area disposed adjacent to the display area, and a cover window including a transmissive area corresponding to the display area and a non-transmissive area corresponding to the peripheral area. The cover window may include a base member, a first print layer formed on a first surface of the base member, and a second print layer formed on the first print layer. The second print layer may include an opening exposing the first print layer, the opening may be disposed in the non-transmissive area, the first print layer and the second print layer may have a same color, and an amount of matting agent included in the second print layer may be greater than an amount of matting agent included in the first print layer.

According to the embodiments, it is possible to improve the visibility of marks represented by the print layer while reducing the manufacturing cost of the print layer included in the cover window of the display device.

### BRIEF DESCRIPTION OF THE DRAWINGS

FIG. 1 is an exploded perspective view of a display device according to an embodiment.

FIG. 2 is a picture of a part of a rear surface of a cover window of the display device shown in FIG. 1.

FIG. 3 is a top plan view of a part of the rear surface of the cover window of the display device according to an embodiment.

FIG. 4 is a schematic cross-sectional view of the cover window of FIG. 3, taken along line A1-A2.

FIG. 5 illustrates a range of gloss levels of a print layer of the cover window according to an embodiment.

FIG. 6 is a table that shows the content of a matting agent included in the print layer of the cover window, the degree of gloss, and a gloss image of a first print layer according to an embodiment.

FIG. 7 is a photograph of a mark of the print layer disposed in the non-transmissive area of the cover window according to an embodiment and a comparative example observed with different measurement positions.

### DETAILED DESCRIPTION OF THE EMBODIMENTS

Hereinafter, with reference to accompanying drawings, various embodiments of the disclosure will be described in detail and thus a person of an ordinary skill can readily practice in the technical field to which the disclosure belongs. The disclosure may be embodied in many different forms and is not limited to the embodiments described herein.

In order to clearly explain the disclosure, parts irrelevant to the description have been omitted, and the same reference numerals should be attached to the same or similar constituent elements throughout the specification.

In addition, since the size and thickness of each component shown in the drawing is arbitrarily shown for better understanding and ease of description, the disclosure is not necessarily limited to what is shown. In the drawings, the thickness of layers, films, panels, regions, etc., are exaggerated for clarity. In addition, in the drawing, the thickness of some layers and regions is exaggerated for better understanding and ease of description.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In addition, unless explicitly described to the contrary, the word “comprise”, and variations such as “comprises” or “comprising”, will be understood to imply the inclusion of stated elements but not the exclusion of any other elements. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Further, throughout the specification, when it is referred to as “planar” or “in a plan view”, it means the case where a target is viewed from above, and when it is referred to as “in a cross-section”, it means the case where a cross-section obtained by vertically cutting the target part is viewed from the side.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

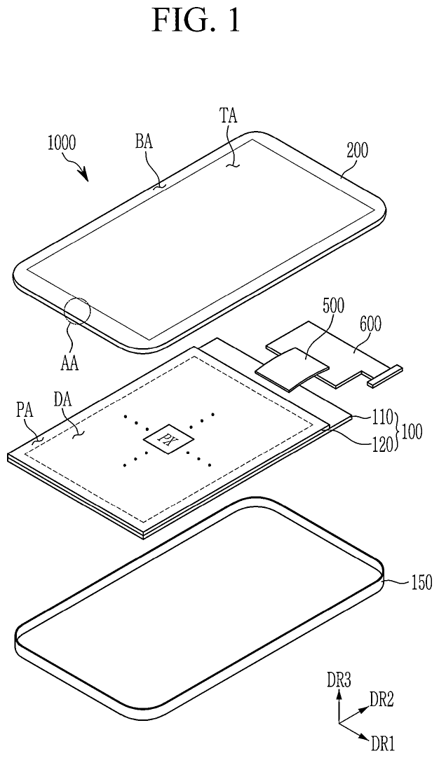

First, referring to FIG. 1, a display device according to embodiment will be described.

FIG. 1 is an exploded perspective view of a display device according to an embodiment.

FIG. 1 illustrates a portable terminal as an example of a display device 1000 according to an embodiment, but the disclosure is not limited thereto. The portable terminal may be various display devices such as a tablet PC, a smart phone, a personal digital assistant (PDA), a portable multimedia player (PMP), a game device, a wrist watch type of electronic device, and the like. However, the display device 1000 according to an embodiment is not limited thereto. The display device 1000 according to an embodiment may be large-sized electronic equipment such as a television or an external billboard, as well as medium and small sized electronic equipment such as a personal computer, laptop computer, car navigation unit, and camera.

Referring to FIG. 1, a display device 1000 according to an embodiment may include a display panel 100, a cover window 200, and a case member 150.

The display panel 100 may include a display area DA, which is an area where an image can be displayed, and a peripheral area PA disposed at the periphery of the display area DA. The display area DA may include multiple pixels PX, which are units for displaying images. The peripheral area PA may be an area that does not display an image.

The display panel 100 may be a display panel of various display devices such as a liquid crystal display (LCD) and an organic light emitting diode (OLED) display.

The display panel 100 may include a substrate 110 and an encapsulation portion 120. Multiple signal lines, multiple transistors, and multiple pixel electrodes may be disposed between the substrate 110 and the encapsulation portion 120. A pixel electrode may be electrically connected to at least one transistor.

For example, in case that the display panel 100 is a display panel of a light emitting display device, multiple light emitting elements may be disposed between the substrate 110 and the encapsulation portion 120. The light emitting element may include a pixel electrode, a common electrode, and at least one emission layer disposed between the pixel electrode and the common electrode. The emission layer may be an organic emission layer including an organic light emitting material or an inorganic emission layer including an inorganic light emitting material.

One pixel electrode may be disposed in each pixel PX, but the disclosure is not limited thereto.

The encapsulation portion 120 may be a substrate and may include multiple insulation layers. For example, the encapsulation portion 120 may include at least one inorganic insulation layer and at least one organic insulation layer. The encapsulation portion 120 may protect the light emitting element by sealing the light emitting element from the outside.

The encapsulation portion 120 may expose a surface of an edge area of the substrate 110 without covering it.

The display panel 100 may have a display surface for displaying images and a rear surface opposite to the display surface. The display surface may be an upper surface of the encapsulation portion 120, and the rear surface may be a lower surface of the substrate 110.

The display surface on which an image is displayed may be substantially parallel to a plane defined by a first direction DR1 and a second direction DR2, and a normal direction of the display surface may be a third direction DR3. However, the directions indicated by these directions may be converted into other directions as a relative concept.

The cover window 200 may overlap the display panel 100 in a plan view. In FIG. 1, the cover window 200 may be disposed on the display panel 100.

The cover window 200 may include a transmissive area TA through which an image provided by the display panel 100 can be transmitted, and a non-transmissive area BA disposed at the periphery of the transmissive area TA. The transmissive area TA may correspond to the display area DA of the display panel 100, and the non-transmissive area BA may correspond to the peripheral area PA of the display panel 100. The non-transmissive area BA may be disposed on the edge area of the cover window 200, and the transmissive area TA may be surrounded by the non-transmissive area BA. The non-transmissive area BA may be also called a light blocking area.

The case member 150 may be disposed on a lower portion of the display panel 100 to accommodate the display panel 100. The case member 150 may be combined with the cover window 200 with the display panel 100 interposed between the case member 150 and the cover window 200.

The display device 1000 according to an embodiment may further include a flexible printed circuit substrate 500.

An end of the flexible printed circuit substrate 500 may be electrically connected to a surface of the substrate 110 exposed by the encapsulation portion 120. The flexible printed circuit substrate 500 may be bent toward the rear surface of the display panel 100.

The display device 1000 according to an embodiment may further include a printed circuit board 600 electrically connected to another end of the flexible printed circuit substrate 500.

The printed circuit board 600 may output a signal to the display panel 100 or receive a signal from the display panel 100 through the flexible printed circuit substrate 500. The printed circuit board 600 or the another end of the flexible printed circuit substrate 500 may be attached to the lower portion of the substrate 110 in a coupled state as the flexible printed circuit substrate 500 is bent.

The display device 1000 according to an embodiment may further include a touch portion (not illustrated). The touch portion may be disposed between the cover window 200 and the display panel 100. However, the disclosure is not limited thereto, and the touch portion may be disposed inside the display panel 100 according to embodiments. The touch portion may operate in various ways such as a resistive film type, a capacitance type, or an electromagnetic induction type, and may detect touch or hovering from the outside.

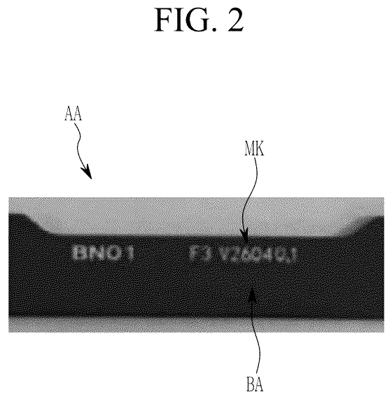

Referring to FIG. 2 to FIG. 4, together with FIG. 1, the cover window according to an embodiment will be described in detail.

FIG. 2 is a picture of a part of the rear surface of the cover window of the display device shown in FIG. 1.

FIG. 2 illustrates a part AA of the rear surface of the cover window 200 of the display device 1000 illustrated in FIG. 1. The rear surface of the cover window 200 may be a surface facing the display panel 100 and may include a mark MK disposed in the non-transmissive area BA. The mark MK may be in a form of letters, numbers, patterns, and the like and may identify the corresponding display device from other display devices or indicate information about the corresponding display device.

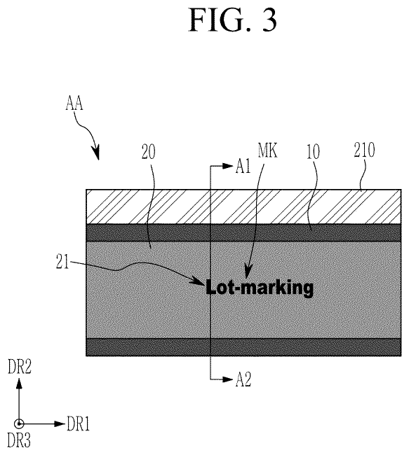

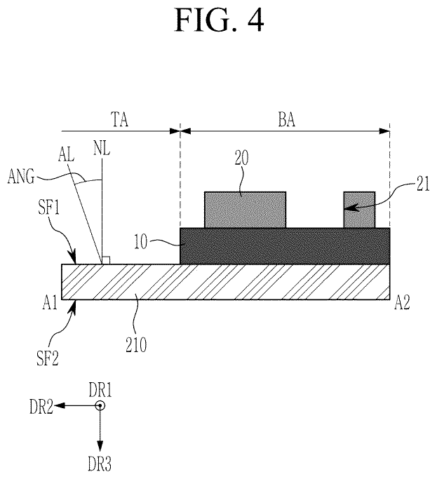

FIG. 3 is a top plan view of a part of the rear surface of the display device according to an embodiment, and FIG. 4 is a schematic cross-sectional view of the cover window shown in FIG. 3, taken along line A1-A2.

Referring to FIG. 3 and FIG. 4, the cover window 200 according to an embodiment may include a base member 210, a first print layer 10, and a second print layer 20.

The base member 210 may include an insulating material such as glass, sapphire, or plastic.

Referring to FIG. 4, in a cross-sectional view, the base member 210 may include a bottom surface SF1 and a top surface SF2. The bottom surface SF1 may be a surface facing the display panel 100 and may be referred to as the rear surface as mentioned above. The top surface SF2 may face the outside of the display device 1000 and the bottom surface SF1.

A portion of the bottom surface SF1 corresponding to the transmissive area TA may be substantially flat, and a portion of the top surface SF2 corresponding to the transmissive area TA may be substantially flat. The portion of the bottom surface SF1 which corresponds to the non-transmissive area BA may be generally flat, but may be bent to form a curved surface. Similarly, a portion of the top surface SF2, which corresponds to non-transmissive area BA may be generally flat, but may be bent to form a curved surface.

The bottom surface SF1 and the top surface SF2 corresponding to the transmissive area TA may be parallel to a plane (a direction in which they are viewed is called a plan view) formed by the first direction DR1 and the second direction DR2. The bottom surface SF1 and the top surface SF2 corresponding to the non-transmissive area BA may be generally parallel to the plane formed by the first direction DR1 and the second direction DR2, but in another embodiment, the bottom surface SF1 corresponding to the non-transmissive area BA may be parallel to the plane and the top surface SF2 may form a curved surface.

A thickness of the base member 210 corresponding to the non-transmissive area BA may be constant in an embodiment, or may gradually decrease toward an edge of the base member 210 in another embodiment. The base member 210 corresponding to the transmissive area TA may have a substantially constant thickness.

The first print layer 10 may be formed on the cover window 200 in the non-transmissive area BA. The first print layer 10 may be black. However, the disclosure is not limited thereto, and the first print layer 10 may have various colors such as chromatic or metallic colors. The first print layer 10 may have a light blocking function.

The first print layer 10 may be directly disposed on the bottom surface SF1 of the base member 210 and contact the bottom surface SF1. The first print layer 10 may be formed by being directly printed on the bottom surface SF1 of the base member 210. For example, the first print layer 10 may be formed on the bottom surface SF1 of the base member 210 by various methods such as spraying, deposition, coating, and printing processes.

A second print layer 20 may be directly disposed on the first print layer 10. The second print layer 20 and the first print layer 10 may be disposed on different layers. For example, the first print layer 10 may be disposed between the base member 210 and the second print layer 20, and the first print layer 10 may contact the base member 210 and the second print layer 20. The second print layer 20 may be formed corresponding to the non-transmissive area BA of the cover window 200, and may have an area equal to or smaller than an area of the first print layer 10.

A color of the second print layer 20 and a color of the first print layer 10 may be the same. For example, the first print layer 10 and the second print layer 20 may have a same black color.

The first print layer 10 and the second print layer 20 may include a resin material mixed with pigments for color implementation such as an acryl-based resin, an epoxy resin, polyurethane, and silicone.

In an embodiment, the second print layer 20 may further include a matting agent. The first print layer 10 may also include a matting agent, but in case that the first print layer 10 includes a matting agent, the first print layer 10 may include a smaller amount of the matting agent than the second print layer 20.

In an embodiment, the matting agent may include, for example, silica (SiO₂). In an embodiment, the matting agent may include wax or an organic material including polyethylene, polypropylene, carnauba, polytetrafluorethylene (PTFE), or amide.

The second print layer 20 may have an opening 21 on an area corresponding to the mark MK. The area where the opening 21 is formed may overlap the first print layer 10 in a plan view. As shown in FIG. 4, the opening 21 may be formed up to the upper surface of the first print layer 10 to expose the upper surface of the first print layer 10.

A space within the opening 21 may be empty or filled with a material different from a material of the print layers 10 and 20.

In a plan view, the opening 21 of the second print layer 20 may form the mark MK. Since the second print layer 20 is not positioned in the mark MK area, the first print layer 10 may be visible from the outside through the opening 21.

The second print layer 20 may be formed on the first print layer 10 by a method such as a spray process, deposition process, coating process, or printing process, and the second print layer 20 may be patterned to form the opening 21. The patterning may be carried out using laser processing, but the disclosure is not limited thereto.

According to an embodiment, only the first print layer 10 and the second print layer 20 may be disposed in the print layer printed on the bottom surface SF1 of the base member 210. For example, print layers disposed on other layers other than the first print layer 10 and the second print layer 20 may not be disposed on the bottom surface SF1 of the base member 210. Accordingly, the cost and time of the printing process of the non-transmissive area BA of the cover window 200 can be saved.

According to an embodiment, a film such as PET may be further disposed between the first print layer 10 and the second print layer 20. According to another embodiment, a film such as PET may be further disposed on the second print layer 20.

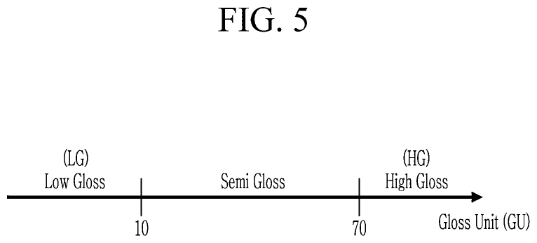

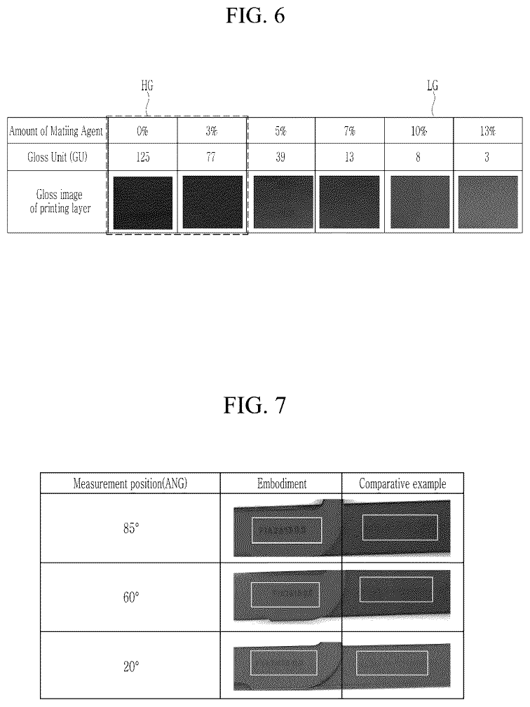

Along with the drawings described above, referring to FIG. 5 and FIG. 6, the first and second print layers 10 and 20 of the cover window 200 according to an embodiment will be described.

FIG. 5 illustrates a range of gloss levels of a print layer of the cover window according to an embodiment, and FIG. 6 is a table that shows the content of the matting agent included in the print layer of the cover window, the degree of gloss, and the gloss image of the first print layer according to an embodiment.

Referring to FIG. 5 together with the above-described drawings, the gloss of the first print layer 10 of the cover window 200 according to an embodiment may have a first gloss HG, and the gloss of the second print layer 20 may have a second gloss LG that is lower than the first gloss HG. The first gloss HG may be greater than or equal to about 70 gloss units (GU), and the second gloss LG may be less than or equal to about 10 GU. A difference between the first gloss HG and the second gloss LG may be greater than or equal to about 60 GU.

The gloss measured may be a value measured a cover window at a standard measurement angle of 60 degrees with a gloss meter. Referring to FIG. 4, the standard measurement angle may be that a measurement angle ANG between a normal line NL that is vertical to the bottom surface SF1 of the base member 210 and a measurement direction line AL connecting a point where the normal line NL and the bottom surface SF1 meet at a position to be measured is 60 degrees.

Referring to FIG. 6, as the glass unit GU increases, a gloss image of the print layer may be recognized as a darker and clearer black due to the glossy characteristics. Therefore, as shown in FIG. 3, the first print layer 10, which is recognized through the opening 21 of the second print layer 20, is darker than the surroundings, and thus the mark MK may be clearly recognized.

According to the embodiment, as described above, the amount of the matting agent included in the first print layer 10 and the amount of the matting agent included in the second print layer 20 may be different to differentiate gloss between the first print layer 10 and the second print layer 20.

For example, the first print layer 10 may not include matting agent or may include less than or equal to about 3% of a matting agent for high gloss characteristics. For example, the first print layer 10 may include a material containing a matting agent. The matting agent may be in a range of about 0% to 3% of the material of the first print layer 10. On the other hand, the second print layer 20 may include greater than or equal to about 10% of a matting agent for low gloss characteristics. For example, the second print layer 20 may include a material containing a matting agent. The matting agent may be greater than or equal to about 10% of the material of the second print layer 10. Referring to FIG. 6, in case that an amount of the matting agent is greater than 10%, gloss of less than 10 GU may be obtained, and in case that an amount of the matting agent is less than 3%, gloss of greater than 70 GU may be obtained.

As described, in case that the second print layer 20 includes an amount of the matting agent more than the first print layer 10, a difference between the surface roughness of the second print layer 20 and the surface roughness of the first print layer 10 may be relatively large. Accordingly, the amount of light scattering on the surface of the second print layer 20 may be greater than the amount of light scattering on the surface of the first print layer 10, and the difference between the gloss of the surfaces of the two print layers 10 and 20 may also increase. As a result, the first print layer 10 viewed through the opening 21 of the second print layer 20 may be viewed more clearly in contrast to the second print layer 20 around the opening 21.

Referring to FIG. 7, a result of the mark MK of the cover window 200 according to the embodiment with different measurement positions and a result of a mark of a cover window according to a comparative example with different measurement positions will be compared.

FIG. 7 is a photograph of a mark of the print layer disposed in the non-transmissive area of the cover window according to an embodiment and a comparative example observed with different measurement positions.

Specifically, FIG. 7 is a photograph of a mark disposed in the non-transmissive area of the cover window while changing a measurement angle ANG between a normal line that is perpendicular to the bottom surface of the base member of the cover window and a measurement direction line connecting a point where the normal line and the bottom surface meet at and the position to be measured according to the embodiment and the comparative example, with 20 degrees, 60 degrees, and 85 degrees. Compared to the comparative example in which the mark is hardly recognized, it can be confirmed that the mark of the cover window according to the embodiment is recognized more clearly.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display panel including a display area including a plurality of pixels and a peripheral area disposed adjacent to the display area; and
a cover window including a transmissive area corresponding to the display area and a non-transmissive area corresponding to the peripheral area, wherein
the cover window comprises:
a base member;
a first print layer formed on a first surface of the base member; and
a second print layer formed on the first print layer,
the second print layer comprises an opening exposing the first print layer,
the opening is disposed in the non-transmissive area,
the first print layer and the second print layer have a same color, and
a gloss of the first print layer is greater than a gloss of the second print layer.

2. The display device of claim 1, wherein
the gloss of the first print layer is greater than or equal to about 70 gloss unit (GU), and
the gloss of the second print layer is less than or equal to about 10 GU.

3. The display device of claim 2, wherein a difference between the gloss of the first print layer and the gloss of the second print layer is greater than or equal to about 60 GU.

4. The display device of claim 2, wherein the second print layer includes a material containing a matting agent.

5. The display device of claim 4, wherein the matting agent is greater than or equal to about 10% of the material of the second print layer.

6. The display device of claim 5, wherein
the first print layer includes a material containing the matting agent, and
the matting agent is in a range of about 0% to about 3% of the material of the first print layer.

7. The display device of claim 1, wherein the first print layer and the second print layer are only print layers disposed on the first surface of the base member.

8. The display device of claim 7, wherein the first print layer contacts the base member and the second print layer.

9. The display device of claim 1, wherein the first surface is a plane that faces the display panel.

10. The display device of claim 1, wherein in a plan view on the first surface, the opening has a shape that indicates information of the display device.

11. A cover window comprising:
a base member;
a first print layer formed on a first surface of the base member; and
a second print layer formed on the first print layer, wherein
the second print layer comprises an opening exposing the first print layer,
the first print layer and the second print layer have a same color, and
a gloss of the first print layer is greater than a gloss of the second print layer.

12. The cover window of claim 11, wherein
the gloss of the first print layer is greater than or equal to about 70 gloss unit (GU), and
the gloss of the second print layer is less than or equal to about 10 GU.

13. The cover window of claim 12, wherein a difference between the gloss of the first print layer and the gloss of the second print layer is greater than or equal to about 60 GU.

14. The cover window of claim 12, wherein the second print layer includes a material containing a matting agent.

15. The cover window of claim 14, wherein the matting agent is greater than or equal to about 10% of the material of the second print layer.

16. The cover window of claim 15, wherein
the first print layer includes a material containing the matting agent, and
the matting agent is in a range of about 0% to about 3% of the material of the first print layer.

17. The cover window of claim 11, wherein the first print layer and the second print layer are only print layers disposed on the first surface of the base member.

18. The cover window of claim 17, wherein the first print layer contacts the base member and the second print layer.

19. The cover window of claim 11, wherein in a plan view on the first surface, the opening has a shape that indicates information of a display device the cover window is disposed on.

20. A display device comprising:
a display panel including a display area including a plurality of pixels and a peripheral area disposed adjacent to the display area; and
a cover window including a transmissive area corresponding to the display area and a non-transmissive area corresponding to the peripheral area, wherein
the cover window comprises:
a base member;
a first print layer formed on a first surface of the base member; and
a second print layer formed on the first print layer,
the second print layer comprises an opening exposing the first print layer,
the opening is disposed in the non-transmissive area,
the first print layer and the second print layer have a same color, and
an amount of a matting agent included in the second print layer is greater than an amount of the matting agent included in the first print layer.
